(19) United States
(12) Patent Application Publication
(10) Pub. No.: US 2026/0123326 A1
(43) Pub. Date: Apr. 30, 2026

(54) APPARATUS FOR TREATING SUBSTRATE

(71) Applicant: SEMES CO., LTD., Cheonan-si (KR)

(72) Inventors: Hyung Gyu KIM, Ansan-si (KR); Seung Hoon OH, Cheonan-si (KR)

(73) Assignee: SEMES CO., LTD., Cheonan-si (KR)

(21) Appl. No.: 19/003,519

(22) Filed: Dec. 27, 2024

(30) Foreign Application Priority Data
Dec. 28, 2023 (KR) 10-2023-0195337

(51) Int. Cl. H01L 21/67

(52) U.S. Cl. CPC H10P 72/0408

(57) ABSTRACT

Disclosed is an apparatus for treating a substrate, the apparatus including: a vessel having a treatment space therein; a support unit for supporting a substrate in the treatment space; a supply port provided in the vessel, and for supplying a process fluid to the treatment space; and a filler unit disposed below the substrate supported on the support unit in the treatment space, in which the filler unit includes: a plate disposed opposite the substrate supported on the support unit; and a plurality of legs extending downwardly from a lower surface of the plate to support the plate within the vessel, a bottom wall of the vessel is formed with a groove defined by an inner surface and a bottom surface, the plate is positioned higher than the groove, and each of the plurality of legs is provided to be in contact with the inner surface forming the groove.

### CROSS-REFERENCE TO RELATED APPLICATIONS

This application claims priority to and the benefit of Korean Patent Application No. 10-2023-0195337 filed in the Korean Intellectual Property Office on Dec. 28, 2023, the entire contents of which are incorporated herein by reference.

### TECHNICAL FIELD

The present invention relates to an apparatus for treating a substrate, and more particularly to an apparatus for treating a substrate by using a supercritical fluid.

### BACKGROUND ART

To manufacture semiconductor devices, a desired pattern is formed on a substrate through various processes, such as photography, etching, ashing, ion implantation, and thin film deposition. Various treatment liquids are used in each process, and contaminants and particles are generated during the process. To address this, cleaning processes are essential before and after each process to remove contaminants and particles.

Typically, the cleaning process is accomplished by treating the substrate with chemicals and rinse liquids followed by drying. In recent years, organic solvents, such as isopropyl alcohol (IPA), have been used as rinse liquids, and drying is performed using supercritical fluids.

In devices that utilize supercritical fluids to dry substrates, in general, a substrate is supported within a vessel and a filler is placed below the substrate.

The filler has a plate and legs extending downwardly therefrom. To facilitate removal of the filler from the vessel, the legs of the filler are placed on the bottom wall of the vessel, and the process proceeds in a state where the filler is not fixedly coupled to the vessel.

Meanwhile, when the drying treatment is performed and a supercritical fluid is supplied to the region below the filler, the supercritical fluid causes the filler to vibrate, or the filler to rotate or move. This may cause particles in the filler or uneven drying of the wafer.

### SUMMARY OF THE INVENTION

The present invention has been made in an effort to provide a substrate treating apparatus capable of efficiently treating a substrate.

The present invention has also been made in an effort to provide a substrate treating apparatus capable of minimizing the generation of particles within a vessel during substrate treatment.

The present invention has also been made in an effort to provide a substrate treating apparatus capable of easily mounting a filler unit in a vessel and also preventing vibration, rotation, or movement of the filler unit during substrate treatment.

The present invention has also been made in an effort to provide a substrate treating apparatus capable of uniformly drying a substrate in a supercritical process.

The problem to be solved by the present invention is not limited to the above-mentioned problems, and the problems not mentioned will be clearly understood by those skilled in the art from the descriptions below.

An exemplary embodiment of the present invention provides an apparatus for treating a substrate, the apparatus including: a vessel having a treatment space therein; a support unit for supporting a substrate in the treatment space; a supply port provided in the vessel, and for supplying a process fluid to the treatment space; and a filler unit disposed below the substrate supported on the support unit in the treatment space, in which the filler unit includes: a plate disposed opposite the substrate supported on the support unit; and a plurality of legs extending downwardly from a lower surface of the plate to support the plate within the vessel, a bottom wall of the vessel is formed with a groove defined by an inner surface and a bottom surface, the plate is positioned higher than the groove, and each of the plurality of legs is provided to be in contact with the inner surface forming the groove.

In the exemplary embodiment, the plurality of legs may each have a convex region along a longitudinal direction thereof.

In the exemplary embodiment, each of the plurality of legs may have: a first portion having a cylindrical shape; a second portion extending downwardly from the first portion and provided with a progressively wider cross-sectional area; and a third portion extending downwardly from the second portion and provided with a progressively narrower cross-sectional area, and at a boundary portion of the second portion and the third portion, each of the plurality of legs is in contact with the inner surface forming the groove.

In the exemplary embodiment, the plurality of legs may be each provided with an elastic material.

In the exemplary embodiment, the plurality of legs may be each provided in a polyetheretherketone material.

In the exemplary embodiment, each of the plurality of legs may be provided in point contact with the inner surface forming the groove.

In the exemplary embodiment, each of the plurality of legs may be in contact with the bottom surface forming the groove.

In the exemplary embodiment, the plate may be spaced apart from a bottom wall of the vessel, and the plate may be provided with an area greater than the groove when viewed from above.

In the exemplary embodiment, the supply port may include a first supply port connected to the bottom surface forming the groove.

In the exemplary embodiment, the apparatus may further include an exhaust port connected to the bottom surface forming the groove.

In the exemplary embodiment, the process fluid may be a supercritical fluid.

Another exemplary embodiment of the present invention provides an apparatus for treating a substrate, the apparatus including: a vessel having a treatment space therein; a support unit for supporting a substrate in the treatment space; a supply port provided in the vessel, and for supplying a process fluid to the treatment space; and a filler unit disposed below the substrate supported on the support unit in the treatment space, in which the filler unit includes: a plate disposed opposite the substrate supported on the support unit; and a plurality of legs extending downwardly from a lower surface of the plate to support the plate within the vessel, a bottom wall of the vessel is formed with a groove defined by an inner surface and a bottom surface, the plate is positioned higher than the groove, and the plurality of legs is inserted into the groove in a forced-fit manner.

In the exemplary embodiment, the plurality of legs may be each provided with an elastic material.

In the exemplary embodiment, the plurality of legs may be each provided in a polyetheretherketone material.

In the exemplary embodiment, each of the plurality of legs may be provided to be in point contact with the inner surface forming the groove.

In the exemplary embodiment, the plurality of legs may be three, and a center of a circle defined by the three legs may be concentric with a center of the plate.

In the exemplary embodiment, the three legs may be equally spaced from each other.

Still another exemplary embodiment of the present invention provides an apparatus for treating a substrate, the apparatus including: a vessel having a treatment space therein; a support unit for supporting a substrate in the treatment space; a supply port provided in the vessel and for supplying a process fluid to the treatment space; an exhaust port for exhausting the process fluid from the treatment space; and a filler unit disposed below the substrate supported on the support unit in the treatment space, in which a first supply port that is in contact with a bottom surface of the filler unit is included, the filler unit includes: a plate disposed opposite the substrate supported on the support unit; and a plurality of legs extending downwardly from a lower surface of the plate to support the plate within the vessel, a bottom wall of the vessel is formed with a groove defined by an inner surface and a bottom surface, the plate is positioned higher than the groove, and each of the plurality of legs is provided to be in contact with the inner surface forming the groove, the plurality of legs each has a convex region along a longitudinal direction thereof, each of the plurality of legs is provided to be in point contact with the inner surface forming the groove, each of the plurality of legs is in contact with the bottom surface forming the groove, the plurality of legs is each provided with an elastic material, and the exhaust port is connected to the bottom surface.

In the exemplary embodiment, the plate may be spaced apart from a bottom wall of the vessel, and the plate may be provided with an area greater than the groove when viewed from above.

In the exemplary embodiment, the plurality of legs may be each provided in a polyetheretherketone material, and each of the plurality of legs may have: a first portion having a cylindrical shape; a second portion extending downwardly from the first portion and provided with a progressively wider cross-sectional area; and a third portion extending downwardly from the second portion and provided with a progressively narrower cross-sectional area, and at a boundary portion of the second portion and the third portion, each of the plurality of legs is in contact with the inner surface forming the groove.

According to the exemplary embodiment of the present invention, it is possible to efficiently treat a substrate.

According to the exemplary embodiment of the present invention, it is possible to minimize particles generated within the vessel when performing a supercritical process.

According to the exemplary embodiment of the present invention, it is possible to prevent vibration, rotation, or movement of the filler unit while performing the supercritical process.

According to the exemplary embodiment of the present invention, it is possible to dry uniformly the wafers during the supercritical process.

The effect of the present invention is not limited to the foregoing effects, and the not-mentioned effects will be clearly understood by those skilled in the art from the present specification and the accompanying drawings.

### BRIEF DESCRIPTION OF THE DRAWINGS

FIG. 1 is a top plan view schematically illustrating a substrate treating apparatus according to an exemplary embodiment of the present invention.

FIG. 2 is a diagram schematically illustrating one example of a liquid treating device provided in the substrate treating apparatus according to the exemplary embodiment of the present invention.

FIG. 3 is a diagram schematically illustrating a first exemplary embodiment of a supercritical treatment device provided in the substrate treating apparatus according to the exemplary embodiment of the present invention.

FIG. 4 is a bottom view of a filler unit according to the exemplary embodiment of the present invention.

FIG. 5 is a perspective view of a leg member according to the exemplary embodiment of the present invention.

FIGS. 6 and 7 are drawings schematically illustrating the process of mounting the filler unit according to the exemplary embodiment of the present invention.

### DETAILED DESCRIPTION

Hereinafter, an exemplary embodiment of the present invention will be described more fully hereinafter with reference to the accompanying drawings, in which exemplary embodiments of the invention are illustrated. However, the present invention may be variously implemented and is not limited to the following exemplary embodiments. In the following description of the present invention, a detailed description of known functions and configurations incorporated herein is omitted to avoid making the subject matter of the present invention unclear. In addition, the same reference numerals are used throughout the drawings for parts having similar functions and actions.

Unless explicitly described to the contrary, the word “include” will be understood to imply the inclusion of stated elements but not the exclusion of any other elements. It will be appreciated that terms “including” and “having” are intended to designate the existence of characteristics, numbers, operations, operations, constituent elements, and components described in the specification or a combination thereof, and do not exclude a possibility of the existence or addition of one or more other characteristics, numbers, operations, operations, constituent elements, and components, or a combination thereof in advance.

Singular expressions used herein include plurals expressions unless they have definitely opposite meanings in the context. Accordingly, shapes, sizes, and the like of the elements in the drawing may be exaggerated for clearer description.

An expression, “and/or” includes each of the mentioned items and all of the combinations including one or more of the items. Further, in the present specification, “connected” means not only when member A and member B are directly connected, but also when member A and member B are indirectly connected by interposing member C between member A and member B.

An expression, “and/or” includes each of the mentioned items and all of the combinations including one or more of the items. Further, in the present specification, “connected” means not only when member A and member B are directly connected, but also when member A and member B are indirectly connected by interposing member C between member A and member B.

Exemplary embodiments of the invention may be modified in many forms, and the scope of the invention should not be construed to be limited to the exemplary embodiments below. The present exemplary embodiment is provided to more fully illustrate the present invention to one of ordinary skill in the art. Therefore, the shapes of elements in the drawings are exaggerated to emphasize clearer descriptions.

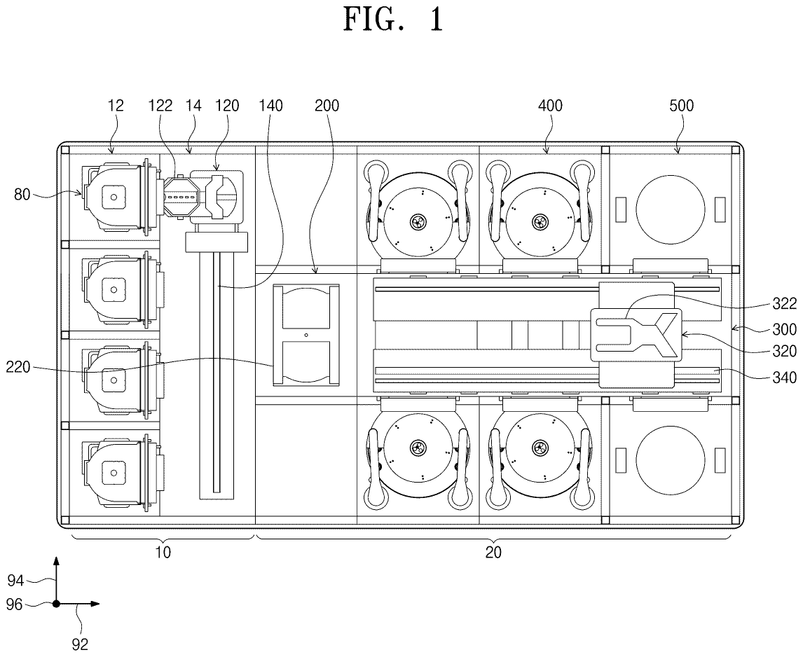

FIG. 1 is a top plan view schematically illustrating a substrate treating system according to an exemplary embodiment of the present invention.

Referring to FIG. 1, a substrate treating system includes an index module 10, a treating module 20, and a controller 30. In one example, the index module 10 and the treating module 20 are disposed along a first direction. Hereinafter, the direction in which the index module 10 and the treating module 20 are disposed is referred to as a first direction 92, and when viewed from above, a direction vertical to the first direction 92 is referred to as a second direction 94, and a direction perpendicular to both the first direction 92 and the second direction 94 is referred to as a third direction 96.

The index module 10 transfers a substrate W from a container 80 in which the substrate W is accommodated to the treating module 20, and makes the substrate W, which has been completely treated in the treating module 20, be accommodated in the container 80. A longitudinal direction of the index module 10 is provided in the second direction 94. The index module 10 includes a load port 12 and an index frame 14. Based on the index frame 14, the load port 12 is located at a side opposite to the treating module 20. The containers 80 in which the substrates W are accommodated are placed on the load ports 12. The load port 12 may be provided in plurality, and the plurality of load ports 12 may be disposed in the second direction 94.

As the container 80, an airtight container, such as a Front Open Unified Pod (FOUP), may be used. The container 80 may be placed on the load port 12 by a transfer means (not illustrated), such as an overhead transfer, an overhead conveyor, or an automatic guided vehicle, or an operator.

An index robot 120 is provided to the index frame 14. A guide rail 140 of which a longitudinal is the second direction 94 is provided within the index frame 14, and the index robot 120 may be provided to be movable on the guide rail 140. The indexing robot 120 includes a hand 122 on which the substrate W is placed, and the hand 122 may be provided to be movable forward and backward, rotatable about the third direction 96, and movable along the third direction 96. The plurality of hands 122 is provided while being spaced apart from each other in the vertical direction, and is capable of independently moving forward and backward.

The treating module 20 includes a buffer unit 200, a transfer unit 300, a liquid treating unit 400, and a supercritical treating unit 500. The buffer unit 200 provides a space in which the substrate W loaded into the treating module 20 and the substrate W unloaded from the treating module 20 stay temporarily. The liquid treating device 400 performs a liquid treatment process of supplying a liquid onto the substrate W and treating the substrate W with the liquid. The supercritical treatment device 500 performs a drying process to remove any residual liquid on the substrate W. The transfer device 300 transfers the substrate W between the buffer unit 200, the liquid treating device 400, and the supercritical treating device 500.

A longitudinal direction of the transport device 300 may be the first direction 92. The buffer unit 200 may be disposed between the index module 10 and the transfer device 300. The liquid treatment device 400 and the supercritical treatment device 500 may be disposed at a lateral portion of the transfer device 300. The liquid treating device 400 and the transfer device 300 may be disposed in the second direction 94. The supercritical treatment device 500 and the transfer device 300 may be disposed along the second direction 94. The buffer unit 200 may be positioned at one end of the transfer device 300.

In one example, the liquid treatment devices 400 are disposed on opposite sides of the transfer device 300 and the supercritical treatment devices 500 are disposed on opposite sides of the transfer device 300, and the liquid treatment devices 400 may be disposed closer to the buffer unit 200 than the supercritical treatment devices 500. At one side of the transfer device 300, the liquid treating devices 400 may be provided in an arrangement of A×B (each of A and B is 1 or a natural larger than 1) in the first direction 92 and the third direction 96. At one side of the transfer device 300, the supercritical treating devices 500 may be provided in number of C×D (each of C and D is 1 or a natural larger than 1) in the first direction 92 and the third direction 96. As described above, one side of the transfer device 300 may be provided with only liquid treating devices 400 and the other side may be provided with only supercritical treatment devices 500.

The transfer device 300 includes a transfer robot 320. A guide rail 340, of which a longitudinal direction is the first direction 92, is provided within the transfer device 300, and the transfer robot 320 may be provided to be movable on the guide rail 340. The transfer robot 320 includes a hand 322 in which the substrate W is placed, and the hand 322 may be provided to be movable forwardly and backwardly, rotatable about the third direction 96, and movable along the third direction 96. The plurality of hands 322 is provided while being spaced apart from each other in the vertical direction, and is capable of independently moving forwardly and backwardly.

The buffer unit 200 includes a plurality of buffers 220 on which the substrate W is placed. The buffers 220 may be disposed while being spaced apart from each other in the third direction 96. A front face and a rear face of the buffer unit 200 are opened. The front face is the face facing the index module 10, and the rear face is the face facing the transfer device 300. The index robot 120 may approach the buffer unit 200 through the front face, and the transfer robot 320 may approach the buffer unit 200 through the rear face.

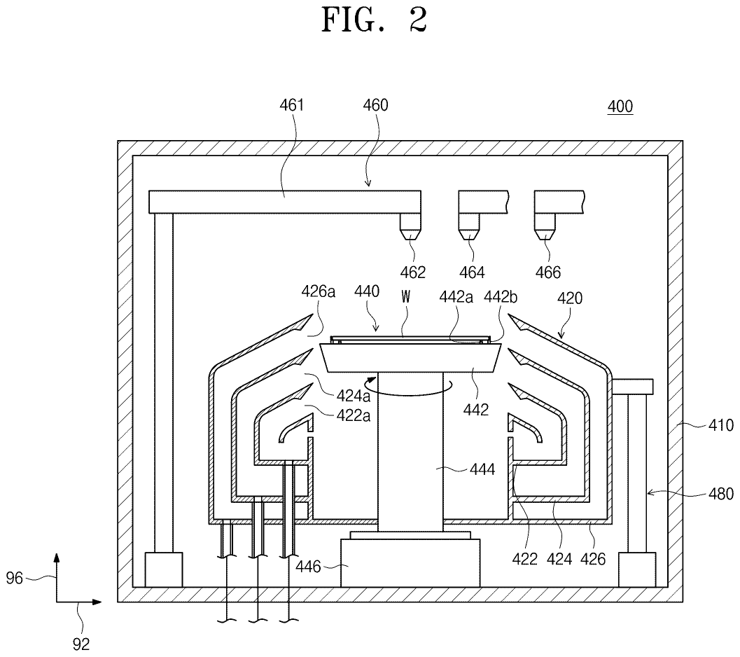

FIG. 2 is a diagram schematically illustrating one example of the liquid treating device provided in the substrate treating apparatus according to the exemplary embodiment of the present invention.

FIG. 2 is a diagram schematically illustrating one example of the liquid treating device of FIG. 2.

Referring to FIG. 2, the liquid treating device 400 includes a housing 410, a cup 420, a support unit 440, a liquid supply unit 460, and a lifting unit 480. The housing 410 is provided in a generally rectangular parallelepiped shape. The cup 420, the support unit 440, and the liquid supply unit 460 are disposed in the housing 410.

The cup 420 has a treatment space with an open top, and the substrate W is liquid-treated in the treatment space. The support unit 440 supports the substrate W in the treatment space. The liquid supply unit 460 supplies the liquid onto the substrate W supported by the support unit 440. The liquid may be provided in a plurality of types, and may be sequentially supplied onto the substrate W. The lifting unit 480 adjusts a relative height between the cup 420 and the support unit 440.

According to the example, the cup 420 includes a plurality of recovery containers 422, 424, and 426. Each of the recovery containers 422, 424, and 426 has a recovery space of recovering the liquid used for the treatment of the substrate. Each of the recovery containers 422, 424, and 426 is provided in a ring shape surrounding the support unit 440. The pre-treatment liquid scattered by the rotation of the substrate W when the liquid treatment process progresses is introduced into the recovery space through inlets 422a, 424a, and 426a of the recovery containers 422, 424, and 426, respectively. According to the example, the cup 420 includes a first recovery container 422, a second recovery container 424, and a third recovery container 426. The first recovery container 422 is disposed to surround the support unit 440, the second recovery container 424 is disposed to surround the first recovery container 422, and the third recovery container 426 is disposed to surround the second recovery container 424. A second inlet 424a, which introduces the liquid into the second recovery container 424, may be positioned above a first inlet 422a, which introduces the liquid into the first recovery container 422, and a third inlet 426a, which introduces the liquid into the third recovery container 426, may be positioned above the second inlet 424a.

The support unit 440 includes a support plate 442 and a driving shaft 444. An upper surface of the support plate 442 may be provided in a generally circular shape, and may have a diameter larger than a diameter of the substrate W. In the center portion of the support plate 442, a support pin 442a is provided to support the rear surface of the substrate W, and the support pin 442a is provided with its upper end protruding from the support plate 442 so that the substrate W is spaced apart from the support plate 442 by a certain distance. A chuck pin 442b is provided to an edge of the support plate 442. The chuck pin 442b is provided to protrude upward from the support plate 442, and supports the lateral portion of the substrate W so that the substrate W is not separated from the support unit 440 when the substrate W is rotated. The drive shaft 444 is driven by a driver 446, is connected to the center of the bottom surface of the substrate W, and rotates the support plate 442 with respect to the central axis thereof.

According to the example, the liquid supply unit 460 includes a first nozzle 462, a second nozzle 464, and a third nozzle 466. The first nozzle 462 supplies a first liquid onto the substrate W. The first liquid may be the liquid of removing a film or foreign substances residual on the substrate W. The second nozzle 464 supplies a second liquid onto the substrate W. The second liquid may be the liquid well soluble in a third liquid. For example, the second liquid may be more soluble in the third liquid than the first liquid. The second liquid may be the liquid that neutralizes the first liquid supplied onto the substrate W. Further, the second liquid may be the liquid that neutralizes the first liquid and at the same time is better soluble in the third liquid than the first liquid. According to one example, the second liquid may be water. The third nozzle 466 supplies the third liquid onto the substrate W. The third liquid may be a liquid that is highly soluble in the supercritical fluid used in the supercritical treatment device 500. For example, the third liquid may be a liquid that is more soluble in the supercritical fluid used in the supercritical treating device 500 compared to the second liquid. According to an example, the third liquid may be an organic solvent. The organic solvent may be isopropyl alcohol (IPA). In addition to isopropyl alcohol, the organic solvent may be ethyl glycol, 1-propanol, tetrahydraulic franc, 4-hydroxyl, 4-methyl, 2-pentanone, 1-butanol, 2-butanol, methanol, ethanol, n-propyl alcohol, dimethylether, and the like. For example, the supercritical fluid may be carbon dioxide. The first nozzle 462, the second nozzle 464, and the third nozzle 466 are supported on different arms 461, and the arms 461 may be moved independently. Optionally, the first nozzle 462, the second nozzle 464, and the third nozzle 466 may be mounted to the same arm and moved at the same time.

The lifting unit 480 moves the cup 420 in the up and down direction. By the up and down movement of the cup 420, a relative height between the cup 420 and the substrate W is changed. Through this, the recovery containers 422, 424, and 426 to which pre-treatment liquids are recovered are changed according to the type of liquid supplied to the substrate W, so that it is possible to separate and recover the liquids. Unlike the description, the cup 420 may be fixedly installed, and the lifting unit 480 may move the support unit 440 in the vertical direction.

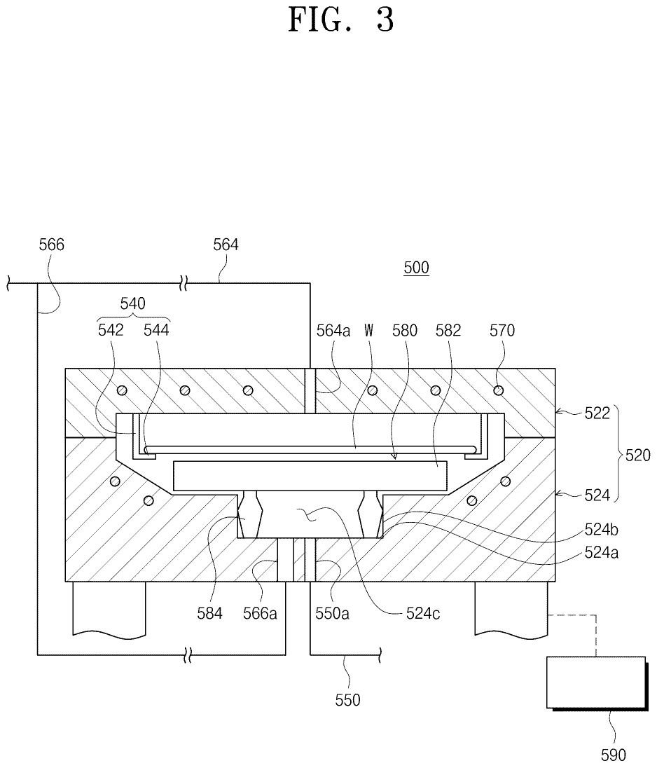

FIG. 3 is a diagram schematically illustrating one example of the a supercritical treatment device of FIG. 1.

Referring to FIG. 3, the supercritical treatment device 500 treats the substrate W for which the liquid treatment has been completed with a supercritical fluid. In the exemplary embodiment, the supercritical treating device 500 dries the substrate W by using a supercritical fluid. The supercritical fluid may be carbon dioxide (CO2) in the supercritical state. Carbon dioxide becomes supercritical when the temperature is raised to 30° C. or higher and the pressure is maintained at 7.4 MPa or higher. Hereinafter, the process fluid will be described as an example in which supercritical carbon dioxide is used.

In one example, the supercritical treating device 500 removes a liquid on the substrate W by using the supercritical fluid. The supercritical treating device 500 includes a vessel 520, a support unit 540, a fluid supply unit 560, and a filler unit 580.

The vessel 520 provides a treatment space 502 where the supercritical process is performed. The vessel 520 is provided with a material that is capable of withstanding the critical temperature and critical pressure of the supercritical fluid. The vessel 520 includes an upper body 522 and a lower body 524.

The upper body 522 has a low-sided open space formed therein. An upper wall of the upper body 522 is provided as an upper wall of the vessel 520. Further, a lateral wall of the upper body 522 is provided as a portion of the lateral wall of the vessel 520. The lower body 524 is positioned below the upper body 522. The lower body 524 has a space with an open top therein. The open top surface of the lower body 524 faces the open bottom surface of the upper body 522. A bottom wall of the lower body 524 is provided as a bottom wall of the vessel 520. Further, a lateral wall of the lower body 524 is provided as a portion of the lateral wall of the vessel 520. The upper body 522 and the lower body 524 are combined with each other to provide the treatment space 502 described above.

The upper body 522 and the lower body 524 may open or close the treatment space 502 by relative movement. A drive member 590 moves at least one of the upper body 522 and the lower body 524 in an upward or downward direction. The drive member 590 may be provided by a hydraulic pressure. In the exemplary embodiment, the upper body 522 may be fixed in position and the lower body 524 may be raised and lowered by the drive member 590, such as a cylinder. When the lower body 524 is spaced apart from the upper body 522, the treatment space 502 is opened, and in this case, the substrate W is loaded or unloaded. During the process, the lower body 524 is in close contact with the upper body 522 so that the treatment space 502 is sealed from the outside.

The supercritical treatment device 500 has a heater 570. In one example, the heater 570 is located inside a wall of the vessel 520. In the exemplary embodiment, the heater 570 may be provided in any one of the upper body 522 and lower body 524 forming the vessel 520, or in each of the upper body 522 and lower body 524. The heater 570 heats the treatment space 502 of the vessel 520 such that the fluid supplied into the treatment space 502 of the vessel 520 maintains a supercritical state. The treatment space 502 is atmospherized by the supercritical fluid.

A groove 524c defined by a bottom surface 524a and an inner surface 524b is formed in the bottom wall of the vessel 520. The groove 524c may be formed to a predetermined depth. The groove may be provided in a circular shape.

The support unit 540 supports the substrate W in the treatment space 502 of the vessel 520. The support unit 540 includes a fixing rod 542 and a cradle 544. The fixing rod 542 may be fixedly installed on the upper body 522 such that the fixing rod 542 protrudes downwardly from the bottom surface of the upper body 522. A longitudinal direction of the fixing rod 542 may be provided in the up and down direction. The fixing rods 542 may be provided in plurality and may be spaced apart from each other. The fixing rods 542 are disposed so that the substrate W does not interfere with the fixing rods 542 when the substrate W is loaded into or unloaded from the space surrounded by the fixing rods 542. The cradle 544 is coupled to the bottom end of each of the fixing rods 542. The cradle 544 extends from the bottom end of the fixing rod 542 in a horizontal direction relative to the ground. In the exemplary embodiment, the cradle 544 extends in a shape capable of supporting the bottom edge of the substrate W.

A first supply port and a second supply port are formed in the vessel 520. The first supply port 566a and the second supply port 564a supply a supercritical fluid to the interior of the vessel 520.

The first supply port 566a is provided in a center region of the lower wall of the vessel 520. The first supply port 566a is formed in a region where the groove 524c of the vessel 520 is formed. The first supply port 566a is formed at a location that penetrates the lower wall in an up and down direction. The first supply port 566a supplies a supercritical fluid to a space located in the lower portion of the substrate W of the interior space 502 of the vessel 520.

The second supply port 564a is provided in the upper wall of the vessel 520. The second supply port 564a supplies a supercritical fluid into a space located on top of the substrate W in the interior space 502 of the vessel 520. The supercritical fluid supplied from the second supply port 564a is provided to the top surface of the substrate W.

The exhaust port 550a exhausts the fluid that remains inside the vessel 520 to the outside. The exhaust port 550a is provided in the lower wall of the vessel 520. The exhaust port 550a may be positioned adjacent to the first supply port 566a. The exhaust port 550a is provided in a center region of the bottom surface of the vessel 520. The exhaust port 550a is formed in a region where the groove 524c of the vessel 520 is formed. In an exemplary embodiment, the exhaust port 550a is formed at a location that penetrates the lower wall in an up and down direction. In the exemplary embodiment, the diameter of the exhaust port 550a is provided to be smaller than the diameter of the first supply port 566a. The fluid exhausted from the exhaust port 550a includes a supercritical fluid in which an organic solvent is dissolved. The fluid exhausted from the exhaust port 550a may be directed to a regeneration device (not illustrated). In the regeneration device, the fluid may be separated into the supercritical fluid and the organic solvent. In contrast, the fluid exhausted from the exhaust port 550a may be released to the atmosphere via an exhaust line 550.

The fluid supply unit 560 supplies a process fluid to the treatment space 502 of the vessel 520. In one example, the process fluid may be supplied to the treatment space 502 in a supercritical state. Alternatively, the process fluid may be supplied to the treatment space 502 in a gaseous state and phase-change to the supercritical state within the treatment space 502. According to the example, the fluid supply unit 560 includes a main supply line 562, an upper branch line 564, and a lower branch line 566. The upper branch line 564 and the lower branch line 566 are branched from the main supply line 562. The upper branch line 564 is coupled with the second supply port 564a to supply a process fluid from the top of the substrate W placed on the support unit 540. The lower branch line 566 is coupled to the first supply port 566a to supply a process fluid from the lower portion of the substrate W placed on the support unit 540. The exhaust line 550 is coupled to an exhaust port 550a. The supercritical fluid in the treatment space 502 of the vessel 520 is exhausted to the outside of the vessel 520 through the exhaust line 550.

Within the treatment space 502 of the vessel 520, the filler unit 580 is disposed.

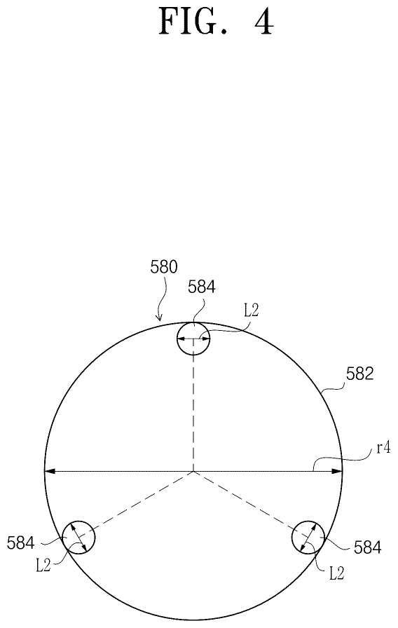

FIG. 4 is a bottom view of the filler unit according to the exemplary embodiment of the present invention.

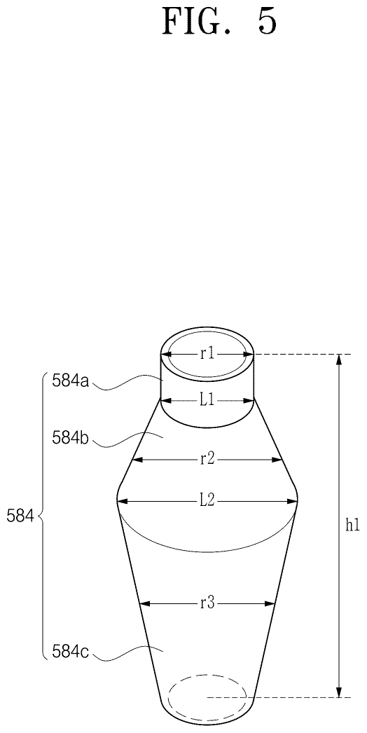

FIG. 5 is a perspective view of the leg member according to the exemplary embodiment of the present invention.

Referring to FIGS. 3 through 5, the filler unit 580 is located at a lower portion of the support unit 540. The filler unit 580 includes a plate 582 and a plurality of legs 584. The plate 582 is disposed opposite the substrate W supported by the support unit 540. The plurality of legs 584 extend downwardly from the bottom surface of the plate 582.

The plate 582 is spaced apart from the bottom wall of the vessel 520. The plate 582 is positioned higher than the groove 524c of the vessel 520. When viewed from above, the area of the plate 582 is larger than the area of the groove 524c of the vessel 520.

A plurality of legs 584 supports the plate 582 within the vessel 520. The plurality of legs 584 is inserted into the grooves 524c of the vessel 520. When the plurality of legs 584 is inserted into the groove, each leg 584 contacts an inner surface of the groove. In one example, the plurality of legs 584 is inserted into the groove in a forced-fit manner.

The plurality of legs 584 may have the same shape as each other. Each of the plurality of legs 584 has a convex region in the longitudinal direction. The plurality of legs 584 contact the bottom surface 524a and the inner surface 524b of the vessel 520, respectively. In the exemplary embodiment, the plurality of legs 584 is in point contact with the inner surface 524b of the vessel 520. The plurality of legs 584 is each provided with an elastic material. In the exemplary embodiment, the plurality of legs 584 are each provided from a polyetheretherketone material.

In the exemplary embodiment, the plurality of legs 584 may be three. The three legs 584 are equally spaced apart from each other. The three legs 584 may be spaced 120° C. apart based on a concentric circle. Here, a circle is defined by the three legs 584. The center of the circle is concentric with the center of the plate 582. In this case, the radius r4 of the concentric circle may be 120 mm.

The height h1 of the plurality of legs 584 is 10 mm to 12 mm. A minimum diameter L1 of the cross-sectional area of the plurality of legs 584 is 3 mm to 5 mm. A maximum diameter L2 of the cross-sectional area of the plurality of legs 584 is 5 mm to 7 mm.

The plurality of legs 584 each includes a first portion 584a, a second portion 584b extending downwardly from the first portion 584a, and a third portion 584c extending downwardly from the first portion 584a.

The first portion 584a is cylindrical in shape. A diameter r1 of the cross-sectional area of the first portion 584a is equal to the minimum diameter L1 of the cross-sectional area of the plurality of legs 584.

The second portion 584a has a progressively larger cross-sectional area as it extends downwardly. The minimum diameter of a cross-sectional area r2 of the second portion 584b is the same as the minimum diameter L1 of the cross-sectional area of the plurality of legs 584. The maximum diameter of the cross-sectional area r2 of the second portion 584a is equal to the maximum diameter L2 of the cross-sectional area of the plurality of legs 584.

The third portion 584c has a progressively narrower cross-sectional area as it extends downward. A minimum diameter of a cross-sectional area r3 of the second portion 584c is equal to the minimum diameter L1 of the cross-sectional area of the plurality of legs 584. A maximum diameter of the cross-sectional area r3 of the third portion 584c is equal to the maximum diameter L2 of the cross-sectional area of the plurality of legs 584.

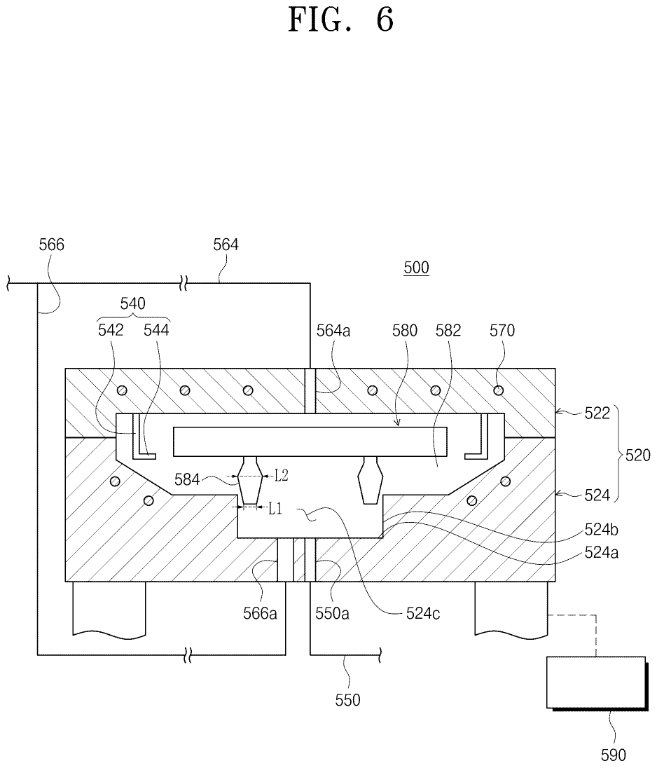

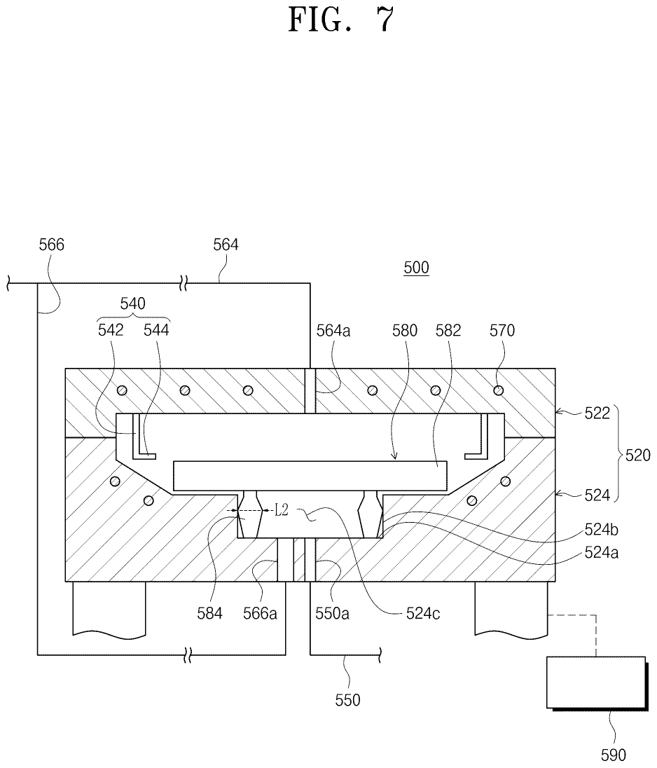

FIGS. 6 and 7 are drawings schematically illustrating the process of mounting the filler unit according to the exemplary embodiment of the present invention.

Referring to FIGS. 6 and 7, the filler unit 580 is provided in the groove 524c. In this case, the maximum diameter of the plurality of legs 584 is L22. The filler unit 580 is mounted in the groove 524c in a forced-fit manner. In this case, the plurality of legs 584 is subjected to pressure, and the maximum diameter of the plurality of legs 584 is increased to L2. Accordingly, the plurality of legs 584 may be in point contact with the inner surface 524b of the lower body 524.

The foregoing detailed description illustrates the present invention. In addition, the foregoing is intended to describe exemplary or various exemplary embodiments for implementing the technical spirit of the present invention, and the present invention may be used in various other combinations, changes, and environments. That is, the foregoing content may be modified or corrected within the scope of the concept of the invention disclosed in the present specification, the scope equivalent to that of the invention, and/or the scope of the skill or knowledge in the art. Accordingly, the detailed description of the invention above is not intended to limit the invention to the disclosed exemplary embodiment. In addition, the appended claims should be construed to include other exemplary embodiments as well. Such modified exemplary embodiments should not be separately understood from the technical spirit or prospects of the present invention.

What is claimed is:

1. An apparatus for treating a substrate, the apparatus comprising:
a vessel having a treatment space therein;
a support unit for supporting a substrate in the treatment space;
a supply port provided in the vessel, and for supplying a process fluid to the treatment space; and
a filler unit disposed below the substrate supported on the support unit in the treatment space,
wherein the filler unit includes:
a plate disposed opposite the substrate supported on the support unit; and
a plurality of legs extending downwardly from a lower surface of the plate to support the plate within the vessel,
a bottom wall of the vessel is formed with a groove defined by an inner surface and a bottom surface,
the plate is positioned higher than the groove, and
each of the plurality of legs is provided to be in contact with the inner surface forming the groove.

2. The apparatus of claim 1, wherein the plurality of legs each has a convex region along a longitudinal direction thereof.

3. The apparatus of claim 1, wherein each of the plurality of legs has:
a first portion having a cylindrical shape;
a second portion extending downwardly from the first portion and provided with a progressively wider cross-sectional area; and
a third portion extending downwardly from the second portion and provided with a progressively narrower cross-sectional area,
at a boundary portion of the second portion and the third portion, each of the plurality of legs is in contact with the inner surface forming the groove.

4. The apparatus of claim 1, wherein the plurality of legs is each provided with an elastic material.

5. The apparatus of claim 1, wherein the plurality of legs is each provided in a polyetheretherketone material.

6. The apparatus of claim 1, wherein each of the plurality of legs is provided in point contact with the inner surface forming the groove.

7. The apparatus of claim 1, wherein each of the plurality of legs is in contact with the bottom surface forming the groove.

8. The apparatus of claim 1, wherein the plate is spaced apart from a bottom wall of the vessel, and
the plate is provided with an area greater than the groove when viewed from above.

9. The apparatus of claim 1, wherein the supply port includes a first supply port connected to the bottom surface forming the groove.

10. The apparatus of claim 1, further comprising:
an exhaust port connected to the bottom surface forming the groove.

11. The apparatus of claim 1, wherein the process fluid is a supercritical fluid.

12. An apparatus for treating a substrate, the apparatus comprising:
a vessel having a treatment space therein;
a support unit for supporting a substrate in the treatment space;
a supply port provided in the vessel, and for supplying a process fluid to the treatment space; and
a filler unit disposed below the substrate supported on the support unit in the treatment space,
wherein the filler unit includes:
a plate disposed opposite the substrate supported on the support unit; and
a plurality of legs extending downwardly from a lower surface of the plate to support the plate within the vessel,
a bottom wall of the vessel is formed with a groove defined by an inner surface and a bottom surface,
the plate is positioned higher than the groove, and
the plurality of legs is inserted into the groove in a forced-fit manner.

13. The apparatus of claim 12, wherein the plurality of legs is each provided with an elastic material.

14. The apparatus of claim 12, wherein the plurality of legs is each provided in a polyetheretherketone material.

15. The apparatus of claim 12, wherein each of the plurality of legs is provided to be in point contact with the inner surface forming the groove.

16. The apparatus of claim 12, wherein the plurality of legs is three, and
a center of a circle defined by the three legs is concentric with a center of the plate.

17. The apparatus of claim 16, wherein the three legs are equally spaced from each other.

18. An apparatus for treating a substrate, the apparatus comprising:
a vessel having a treatment space therein;
a support unit for supporting a substrate in the treatment space;
a supply port provided in the vessel and for supplying a process fluid to the treatment space;
an exhaust port for exhausting the process fluid from the treatment space; and
a filler unit disposed below the substrate supported on the support unit in the treatment space,
wherein a first supply port that is in contact with a bottom surface of the filler unit is included,
the filler unit includes:
a plate disposed opposite the substrate supported on the support unit; and
a plurality of legs extending downwardly from a lower surface of the plate to support the plate within the vessel,
a bottom wall of the vessel is formed with a groove defined by an inner surface and a bottom surface,
the plate is positioned higher than the groove, and
each of the plurality of legs is provided to be in contact with the inner surface forming the groove,
each of the plurality of legs has a convex region along a longitudinal direction thereof,
each of the plurality of legs is provided to be in point contact with the inner surface forming the groove,
each of the plurality of legs is in contact with the bottom surface forming the groove,
the plurality of legs is each provided with an elastic material, and
the exhaust port is connected to the bottom surface.

19. The apparatus of claim 18, wherein the plate is spaced apart from a bottom wall of the vessel, and
the plate is provided with an area greater than the groove when viewed from above.

20. The apparatus of claim 18, wherein the plurality of legs is each provided in a polyetheretherketone material, and
each of the plurality of legs has:
a first portion having a cylindrical shape;
a second portion extending downwardly from the first portion and provided with a progressively wider cross-sectional area; and
a third portion extending downwardly from the second portion and provided with a progressively narrower cross-sectional area, and
at a boundary portion of the second portion and the third portion, each of the plurality of legs is in contact with the inner surface forming the groove.
